(19) United States
(12) Patent Application Publication
(10) Pub. No.: US 2026/0128256 A1
(43) Pub. Date: May 7, 2026

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/437,392

(22) Filed: Dec. 31, 2025

Related U.S. Application Data
(63) Continuation of application No. PCT/JP2024/023002, filed on Jun. 25, 2024.

(30) Foreign Application Priority Data
Jul. 7, 2023 (JP) 2023-112342

(51) Int. Cl. H01J 37/32; H01P 3/02

(52) U.S. Cl. CPC H01J 37/32082; H01J 37/3244; H01P 3/02

(57) ABSTRACT

A plasma processing apparatus includes: a chamber which provides a processing space in an interior of the chamber; a substrate support provided in the processing space; an excitation electrode provided above the substrate support; an emitter provided to emit an electromagnetic wave to a plasma generation space below the excitation electrode; and a resonator provided above the excitation electrode and electromagnetically coupled to the emitter. The resonator includes a conductor part constituting a waveguide. The conductor part is formed with first and second conductors. The first conductor is provided in a first portion extending from a first end of the waveguide to a position corresponding to a quarter of a wavelength in the waveguide of the electromagnetic wave inside the resonator, and the second conductor is provided in a second portion other than the first portion. The first conductor is lower in thermal conductivity than the second conductor.

### CROSS-REFERENCE TO RELATED APPLICATIONS

The application is a Bypass Continuation Application of PCT International Application No. PCT/JP2024/023002, filed on June 25, 2024 and designating the United States, the international application being based upon and claiming the benefit of priority from Japanese Patent Application No. 2023-112342, filed on July 7, 2023, the entire content of which is incorporated herein by reference.

### TECHNICAL FIELD

The present disclosure relates to a plasma processing apparatus.

### BACKGROUND

A plasma processing apparatus is used in processing a substrate. There is known one type of plasma processing apparatus that excites a gas using a radio-frequency wave such as a VHF wave or a UHF wave. The plasma processing apparatus known in the related art includes a processing container, a stage, an upper electrode, an introduction portion, and a waveguide portion. The stage is provided within the processing container. The upper electrode is provided above the stage via a space within the processing container. The introduction portion is an introduction section for a radio-frequency wave. The introduction portion is provided at a lateral end of the space and extends circumferentially around a central axis of the processing container. The waveguide portion is configured to supply a radio-frequency wave to the introduction portion. The waveguide portion includes a resonator configured to provide a waveguide. The

waveguide of the resonator extends circumferentially around the central axis, extends in the extension direction of the central axis, and is connected to the introduction portion.

### Prior Art Document

### Patent Document

### Patent Document 1: Japanese Laid-Open Patent Publication No. 2020-092031

### SUMMARY

According to an example embodiment of the present disclosure, a plasma processing apparatus includes: a chamber which provides a processing space in an interior of the chamber; a substrate support provided in the processing space; an excitation electrode provided above the substrate support; an emitter provided to emit an electromagnetic wave to a plasma generation space below the excitation electrode; and a resonator provided above the excitation electrode and electromagnetically coupled to the emitter, wherein the resonator includes a conductor part constituting a waveguide, the conductor part is formed with a first conductor and a second conductor, the first conductor being provided in a first portion which extends from a first end of the waveguide to a position corresponding to a quarter of a wavelength in the waveguide of the electromagnetic wave inside the resonator, and the second conductor being provided in a second portion other than the first portion, and a thermal conductivity of the first conductor is lower than a thermal conductivity of the second conductor.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is a cross-sectional view taken along line II-II in FIG. 1.

FIG. 3 is a cross-sectional view taken along line III-III in FIG. 1.

FIG. 4 is a cross-sectional view taken along line IV-IV in FIG. 1.

FIG. 5 is a cross-sectional view taken along line V-V in FIG. 1.

FIG. 6 is a diagram illustrating a plasma processing apparatus according to another exemplary embodiment.

FIG. 7 is a cross-sectional view taken along line VII-VII in FIG. 6.

FIG. 8 is a cross-sectional view taken along line VIII-VIII in FIG. 6.

FIG. 9 is a cross-sectional view taken along line IX-IX in FIG. 6.

FIG. 10 is a cross-sectional view taken along line X-X in FIG. 6.

FIG. 11 is a diagram illustrating a plasma processing apparatus according to another exemplary embodiment.

### DETAILED DESCRIPTION

Various exemplary embodiments will be described in detail below with reference to the drawings, in which the same or equivalent parts are designated by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

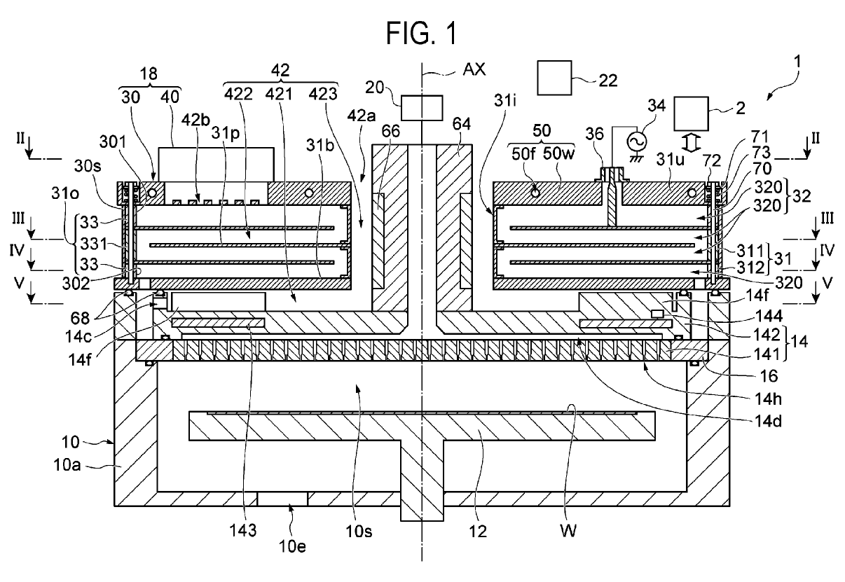

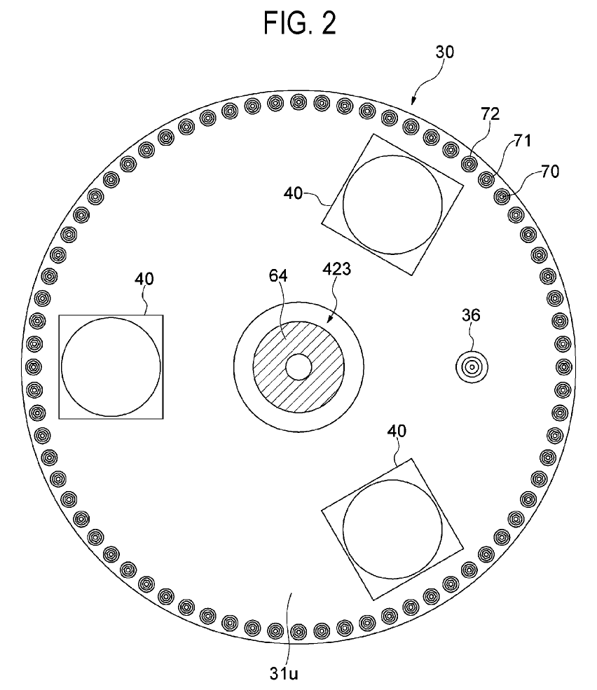

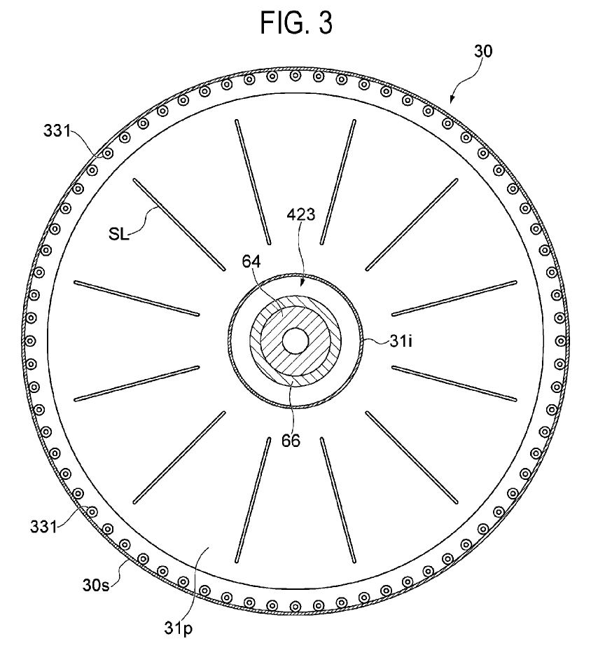

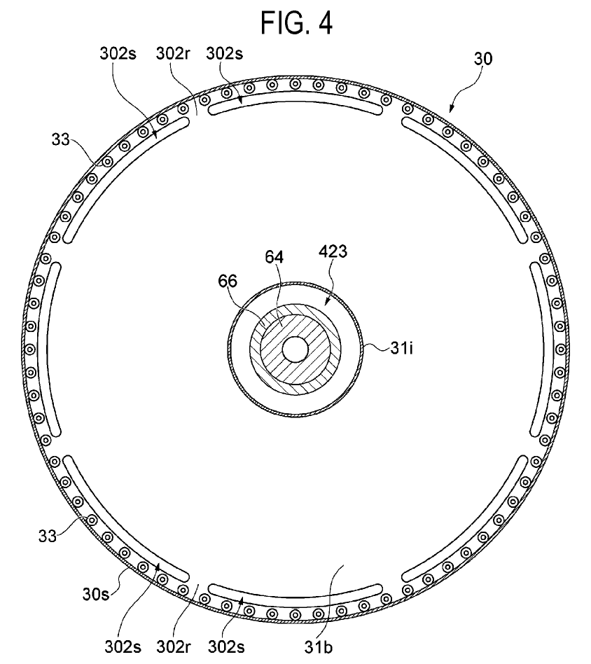

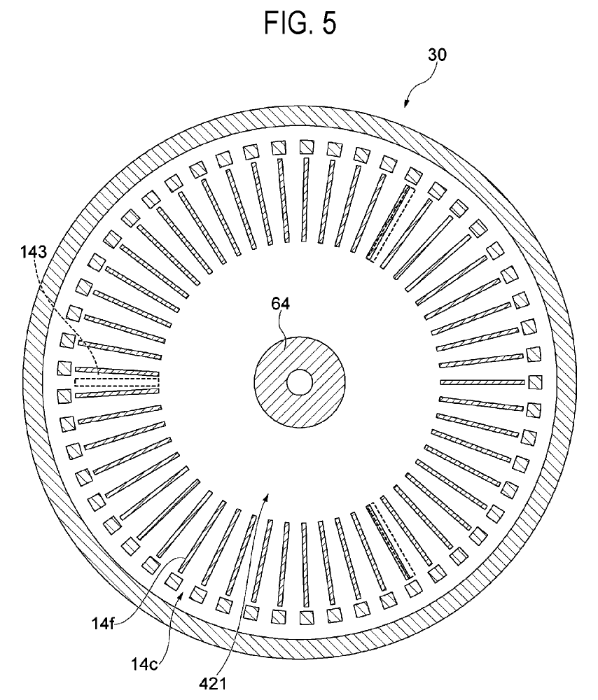

FIG. 1 is a diagram illustrating a plasma processing apparatus according to one exemplary embodiment. FIG. 2 is a cross-sectional view taken along line II-II in FIG. 1. FIG. 3 is a cross-sectional view taken along line III-III in FIG. 1. FIG. 4 is a cross-sectional view taken along line IV-IV in FIG. 1. FIG. 5 is a cross-sectional view taken along line V-V in FIG. 1. A plasma processing apparatus 1 illustrated in FIGS. 1 to 5 includes a chamber 10, a substrate support 12, an excitation electrode 14, an emitter 16, and a resonator 30. The plasma processing apparatus 1 may further include a controller 2.

The chamber 10 has a processing space 10s provided therein. In the plasma processing apparatus 1, a substrate W is processed in the processing space 10s. The chamber 10 is formed of a metal such as aluminum and is grounded. The chamber 10 has a sidewall 10a and is open at an upper end thereof. The chamber 10 and the sidewall 10a may have a substantially cylindrical

shape. The processing space 10s is provided inward of the sidewall 10a. A central axis of each of the chamber 10, the sidewall 10a, and the processing space 10s is an axis AX. The chamber 10 may include a corrosion-resistant film formed on a surface thereof. The corrosion-resistant film may be an yttrium oxide film, an yttrium oxide fluoride film, an yttrium fluoride film, or a ceramic film containing yttrium oxide, yttrium fluoride or the like.

A bottom portion of the chamber 10 is provided with an exhaust port 10e. An exhauster is connected to the exhaust port 10e. The exhauster may include a vacuum pump such as a dry pump and/or a turbomolecular pump, and an automatic pressure control valve.

The substrate support 12 is provided in the processing space 10s. The substrate support 12 is configured to support the substrate W placed on an upper surface thereof in a substantially horizontal posture. The substrate support 12 has a substantially disk-like shape. A central axis of the substrate support 12 is the axis AX.

The excitation electrode 14 is provided above the substrate support 12 via the processing space 10s. The excitation electrode 14 is formed of a conductive material such as metal (e.g., aluminum) and has a substantially disk-like shape. A central axis of the excitation electrode 14 is the axis AX.

The emitter 16 is provided to emit an electromagnetic wave into a plasma generation space. In the plasma processing apparatus 1, the plasma generation space is a space existing within the processing space 10s and below the excitation electrode 14. The electromagnetic wave emitted from the emitter 16 into the plasma generation space may be a radio-frequency wave such as a VHF wave or a UHF wave. The emitter 16 is formed of a dielectric material such as quartz, aluminum nitride, or aluminum oxide. The emitter 16 extends circumferentially around the axis AX. The emitter 16 may have a ring shape. The emitter 16 may extend to

surround the plasma generation space or a shower plate 141 (to be described later). In the plasma processing apparatus 1, the gas in the chamber 10 is excited by the electromagnetic wave emitted from the emitter 16 into the plasma generation space. Accordingly, plasma is generated in the plasma generation space.

In one embodiment, the excitation electrode 14 may include a shower plate 141 and an upper electrode 142. The shower plate 141 is provided above the plasma generation space. The shower plate 141, together with the emitter 16, closes an upper end opening of the chamber 10. The shower plate 141 provides a plurality of gas holes 14h. The plurality of gas holes 14h extend in a thickness direction (vertical direction) of the shower plate 141 and penetrate the shower plate 141.

The upper electrode 142 is provided on the shower plate 141. The upper electrode 142 forms a gas diffusion chamber 14d between the shower plate 141 and the upper electrode 142. A gas supply 20 is connected to the gas diffusion chamber 14d. Gases from the gas supply 20 pass through the gas diffusion chamber 14d and are discharged from the plurality of gas holes 14h into the plasma generation space (the processing space 10s).

In one embodiment, the excitation electrode 14 may include a built-in heating mechanism 143. The heating mechanism 143 may be provided inside the upper electrode 142. The heating mechanism 143 may be an electric heater, for example, a resistive heating element. In this case, the heating mechanism 143 is connected to a heater power supply 22. The heating mechanism 143 generates heat by electric power supplied from the heater power supply 22. The plasma processing apparatus 1 may further include a temperature sensor 144. The temperature sensor 144 may be provided inside the excitation electrode 14 or the upper electrode 142. The temperature sensor 144 includes, for example, a thermocouple. The temperature sensor 144

measures a temperature of the excitation electrode 14. In the plasma processing apparatus 1, the heater power supply 22 and a plurality of fans (to be described later) are controlled by the controller 2 to reduce a difference between a measured temperature value measured by the temperature sensor 144 and a target temperature value for the excitation electrode 14.

The controller 2 is a computer including a processor, a storage such as a memory, and a communication interface. The controller 2 is configured to execute a control program and control individual components of the plasma processing apparatus 1 in accordance with recipe data.

The resonator 30 is provided above the excitation electrode 14. The resonator 30 is electromagnetically coupled to the emitter 16. The resonator 30 provides a waveguide 32. The resonator 30 includes a conductor part 31 which defines the waveguide 32. The conductor part 31 is formed of a conductive material such as a metal.

The resonator 30 includes a first end 301 and a second end 302. The first end 301 is one end of the waveguide 32, and the second end 302 is the other end of the waveguide 32. The resonator 30 is configured to reflect and resonate the electromagnetic wave propagating within the waveguide 32 at the first end 301 and the second end 302. The electromagnetic wave resonating within the resonator 30 is supplied to the emitter 16 from a plurality of slots 302s (to be described later) and emitted into the plasma generation space.

The plasma processing apparatus 1 may further include a radio-frequency power supply 34. The radio-frequency power supply 34 is configured to generate radio-frequency power. The electromagnetic wave introduced into the plasma generation space is generated based on the radio-frequency power generated by the radio-frequency power supply 34. The radio-frequency power supply 34 may be directly connected to the resonator 30 using a coaxial line. That is, the

radio-frequency power supply 34 may be coupled to the waveguide 32 of the resonator 30 without a matcher for impedance matching. The coaxial line may include a connector 36 as a connection portion with respect to the resonator 30. The connector 36 may be connected to the resonator 30 so as to introduce the electromagnetic wave into the resonator 30 from an uppermost layer of a plurality of layers 320 (to be described below) of the waveguide 32. In this case, an inner conductor of the connector 36 is connected to a conductor plate 31p (to be described below) which defines the uppermost layer from below, and an outer conductor of the connector 36 is connected to a conductor plate 31p (an upper wall 31u) which defines an uppermost layer from above.

The conductor part 31 of the resonator 30 includes a first portion 311 and a second portion 312. The first portion 311 includes a portion from the first end 301 of the waveguide 32 to a position corresponding to a quarter of the wavelength of the electromagnetic wave in the waveguide 32 of the resonator 30. The second portion 312 is a portion other than the first portion 311 in the conductor part 31. The second portion 312 may be the entire portion of the conductor part 31, other than the first portion 311. The first portion 311 is formed of a first conductor. The second portion 312 is formed of a second conductor. A thermal conductivity of the first conductor is lower than a thermal conductivity of the second conductor. Therefore, an electrical conductivity of the first conductor is lower than an electrical conductivity of the second conductor. The first conductor includes, for example, stainless steel or brass. The second conductor includes, for example, aluminum or copper. The first portion 311 may include a main body formed of the first conductor and a film covering a surface of the main body. This film may have an electrical conductivity greater than that of the first conductor, and may be formed of, for example, silver, copper, gold, or the like.

In the plasma processing apparatus 1, the first portion 311 of the resonator 30 has a low thermal conductivity, which suppresses the conduction of heat from the excitation electrode 14 via the resonator 30. Therefore, power consumption of the heater power supply 22 is suppressed. Further, in the first portion 311, a voltage of a standing wave is maximized and a current of the standing wave is minimized. Therefore, in the plasma processing apparatus 1, a current loss in the resonator 30 is suppressed.

In one embodiment, the waveguide 32 may have a folded structure including a plurality of folded portions. In this case, the first portion 311 may extend along one of the plurality of folded portions.

In one embodiment, the waveguide 32 may be configured to be axially symmetric or rotationally symmetric with respect to the axis AX. Further, in one embodiment, the conductor part 31 may include an inner portion 31i (or an inner peripheral portion), an outer portion 31o (or an outer peripheral portion), and a plurality of conductor plates 31p. The inner portion 31i and the outer portion 31o extend coaxially with respect to the axis AX. Each of the inner portion 31i and the outer portion 31o may have a substantially cylindrical shape with respect to the axis AX as a central axis thereof. The plurality of conductor plates 31p extend in a radial direction with respect to the axis AX and are arranged parallel to one another in the vertical direction in which the axis AX extends.

The waveguide 32 may also include a plurality of layers 320. The plurality of layers 320 extend in the radial direction with respect to the axis AX between the inner portion 31i and the outer portion 31o, and are arranged alternately with the plurality of conductor plates 31p. Each of the plurality of layers 320 is connected to an upperlying layer located above the respective

layer among the plurality of layers 320 and one of the plurality of folded portions arranged along the inner portion 31i or the outer portion 31o.

In one embodiment, the first end 301 is provided above the second end 302. The first end 301 is provided by the outer portion 31o of the resonator 30. The first end 301 is an outer peripheral end of the uppermost layer among the plurality of layers 320 and surrounds the uppermost layer. The second end 302 is provided by the outer portion 31o of the resonator 30. The second end 302 is an outer peripheral end of a lowermost layer among the plurality of layers 320 and surrounds the lowermost layer. As illustrated in FIG. 4, a plurality of slots 302s are formed in a lowermost conductor plate 31b, which defines the lowermost layer among the plurality of conductor plates 31p from below. The plurality of slots 302s are disposed near or along the second end 302. The plurality of slots 302s are coupled to the emitter 16 outside the excitation electrode 14. The plurality of slots 302s extend circumferentially around the axis AX above the emitter 16. The plurality of slots 302s extend in a circumferential direction around the axis AX and are arranged along the circumferential direction. The plurality of slots 302s are arranged alternately with a plurality of portions 302r in the conductive plate 31b. In this resonator 30, the electromagnetic wave is reflected at the second end 302 toward the first end 301. Further, a portion of the electromagnetic wave propagating in the resonator 30 is coupled to the emitter 16 via the plurality of slots 302s. In this embodiment, the first portion 311 is included in the outer portion 31o and surrounds one or more intermediate layers 320 among the plurality of layers 320.

In one embodiment, the inner portion 31i may be formed of a cylindrical conductor wall extending between the conductor plates 31p adjacent to each other in the vertical direction. The outer portion 31o may be constituted with a plurality of columns 33. In the outer portion 31o, the columns 33 are arranged in the circumferential direction around the axis AX between the

vertically-adjacent conductor plates 31p. Each of the columns 33 is aligned with a corresponding column 33 along the vertical direction. In this embodiment, the first portion 311 is constituted with a plurality of columns 33 (a plurality of columns 331 in the figures) surrounding one or more intermediate layers 320 among the plurality of layers 320. In this embodiment, a thickness (radial thickness) of the conductor wall constituting the inner portion 31i may be smaller than a thickness (radial thickness) of the outer portion 31o. This suppresses the conduction of heat from the excitation electrode 14 via the inner portion 31i.

The plurality of columns 33 may have a cylindrical shape. In this case, bolts 70 may penetrate respective inner holes of the plurality of columns 33, which are aligned along the vertical direction. A lower end of the bolt 70 may be threadedly coupled to the lowermost conductor plate 31b among the plurality of conductor plates 31p. A washer 71 and a nut 72 may be attached to an upper end of the bolt 70, and a coil spring 73 may be provided between the washer 71 and the upper wall 31u.

In one embodiment, the plasma processing apparatus 1 may further include a thin shield plate 30s. The thin shield plate 30s is formed of a metal such as stainless steel. The thin shield plate 30s has a cylindrical shape and surrounds the outer portion 31o of the resonator 30. The thin shield plate 30s suppresses leakage of the electromagnetic wave from the resonator 30.

In one embodiment, the plasma processing apparatus 1 may further include at least one conductive member 68. The conductive member 68 is provided between the resonator 30 and the excitation electrode 14 so as to form a gap between the resonator 30 and the excitation electrode 14. The conductive member 68 is formed of a metal such as stainless steel. The conductive member 68 may have elasticity. The conductive member 68 is, for example, a shield

spiral formed of a metal. The conductive member 68 suppresses the transfer of heat between the resonator 30 and the excitation electrode 14.

The conductive member 68 is interposed between the conductor plate 31b and the excitation electrode 14. Accordingly, the conductive member 68 renders the resonator 30 to be in a conductive state with the excitation electrode 14. Conductive members 68 may be disposed to form a ring around the axis AX. In the illustrated example, two conductive members 68 as the at least one conductive member 68 are disposed in a ring shape around the axis AX. The conductive members 68 may be disposed along places of the resonator 30 where the radio-frequency current flows. In the illustrated example, the two conductive members 68 are disposed along a pair of edges of each of the plurality of slots 302s.

In one embodiment, as illustrated in FIG. 3, a plurality of slits SL may be formed in at least one of the plurality of conductor plates 31p. The plurality of slits SL penetrate the at least one conductor plate 31p in the thickness direction. The plurality of slits SL are arranged along the circumferential direction around the axis AX and extend in the radial direction with respect to the axis AX. The plurality of slits SL suppresses propagation of harmonic in the electromagnetic wave in the circumferential direction. Further, a pressure loss of a heat medium (to be described later) in the waveguide 32 is suppressed.

The plasma processing apparatus 1 may further include a temperature regulator 18. The temperature regulator 18 is configured to supply the heat medium (e.g., a gas such as air) along an upper surface of the excitation electrode 14.

The temperature regulator 18 includes a plurality of fans 40. The temperature regulator 18 provides a flow path 42. The plurality of fans 40 are arranged at approximately equal intervals around the axis AX above the excitation electrode 14. The plurality of fans 40 are configured to form a flow of the heat medium in the flow path 42. In the plasma processing apparatus 1, each of the plurality of fans 40 may suction the heat medium from the flow path 42 and discharge the same therefrom.

The flow path 42 extends from an opening 42a to a plurality of openings 42b. The opening 42a is an inlet through which the heat medium flows into the flow path 42. The plurality of openings 42b are outlets through which the heat medium flows out from the flow path 42. Each of the plurality of openings 42b is open directly below a corresponding fan among the plurality of fans 40.

The flow path 42 is axially symmetric or rotationally symmetric with respect to the axis AX. The flow path 42 includes a partial flow path 421 and a partial flow path 422. The flow path 42 may further include a partial flow path 423.

The partial flow path 421 extends along the upper surface of the excitation electrode 14. The partial flow path 421 is provided between the conductor plate 31b of the resonator 30 and the excitation electrode 14. The partial flow path 421 extends in the radial direction with respect to the axis AX. The partial flow path 422 is connected to the partial flow path 421 via a plurality of communication holes 14c formed in the upper electrode 142. The partial flow path 422 extends alternately in different directions between the plurality of fans 40 and the partial flow path 421. The different directions include a direction approaching the axis AX and a radial direction with respect to the axis AX. The different directions are perpendicular to the axis AX. In one embodiment, the partial flow path 422 of the temperature regulator 18 is formed using the waveguide 32 of the resonator 30. Therefore, the resonator 30 constitutes a heat exchanger for the excitation electrode 14.

The partial flow path 423 extends from the opening 42a to the partial flow path 421. The partial flow path 423 is provided inward of the inner portion 31i of the resonator 30. A central axis of the partial flow path 423 may be the axis AX. That is, the partial flow path 423 may extend vertically along the axis AX to the partial flow path 421.

In the plasma processing apparatus 1, the heat medium introduced from the opening 42a is supplied from the partial flow path 423 to the partial flow path 421, and flows through the partial flow path 421 along the upper surface of the excitation electrode 14. Accordingly, heat exchange occurs between the excitation electrode 14 and the heat medium. Subsequently, the heat medium flows from the partial flow path 421 to the partial flow path 422, and is discharged to the outside of the plasma processing apparatus 1 via the plurality of openings 42b by the plurality of fans 40.

In one embodiment, a heater 66 may be provided inward of the inner portion 31i of the resonator 30. In this embodiment, the heat medium is preheated by the heater 66 and is supplied to the partial flow path 421. For example, the heater 66 may preheat the heat medium to a temperature substantially identical to the temperature of the excitation electrode 14 (e.g., 180 degrees C). This improves temperature controllability of the excitation electrode 14.

In one embodiment, the plasma processing apparatus 1 may further include a gas pipe 64. The gas pipe 64 extends in the vertical direction on an inner side of the inner portion 31i. A central axis of the gas pipe 64 may be located on the axis AX. The gas pipe 64 is connected between the gas diffusion chamber 14d and the gas supply 20. The heater 66 described above may surround the gas pipe 64. Alternatively, the heater 66 may be attached to an outer periphery of the gas pipe 64.

The temperature regulator 18 may further include a cooler 50. The cooler 50 may form a portion of the partial flow path 422. Specifically, the cooler 50 includes a wall 50w, and a coolant flow path 50f provided inside the wall 50w. A coolant is supplied to the coolant flow path 50f from a chiller unit. According to the temperature regulator 18, the heat medium cooled by the cooler 50 in the partial flow path 422 is discharged to the outside of the plasma processing apparatus by the plurality of fans 40. The wall 50w may be the upper wall 31u. The wall 50w may be any one of the plurality of conductor plates 31p of the resonator 30 instead of the upper wall 31u.

In one embodiment, a vertical length (height) of the waveguide 32 of the uppermost layer among the plurality of layers 320 in the waveguide 32 may be longer than vertical lengths (heights) of the waveguides 32 of other layers among the plurality of layers 320. Since the uppermost layer is provided near the plurality of fans 40, a flow velocity of the heat medium in the uppermost layer is high. According to this embodiment, it is possible to suppress the pressure loss of the heat medium in the uppermost layer where the flow velocity is high.

In one embodiment, the excitation electrode 14 may include a plurality of fins 14f. The plurality of fins 14f are provided by the upper electrode 142. The plurality of fins 14f protrude upward, extend in the radial direction with respect to the axis AX, and are arranged in the circumferential direction around the axis AX. Each of the plurality of communication holes 14c is connected to a gap between two adjacent fins among the plurality of fins 14f. The plurality of fins 14f promotes the heat exchange between the excitation electrode 14 and the heat medium.

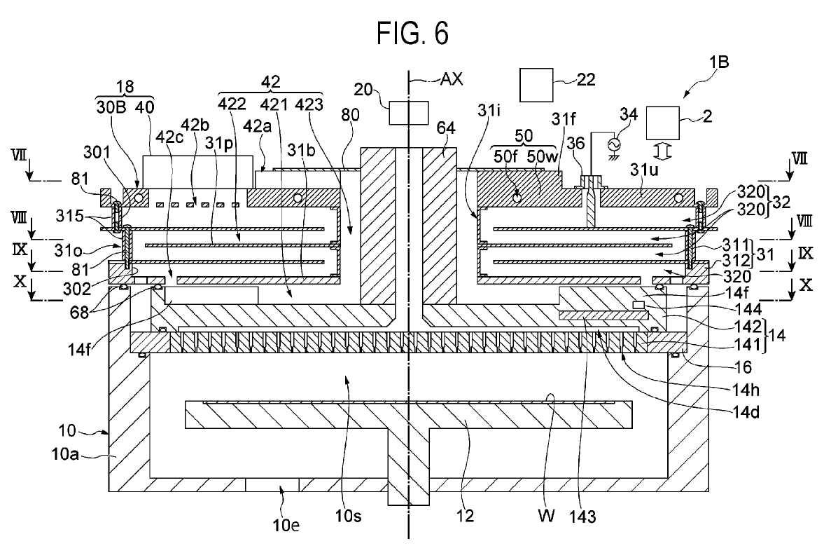

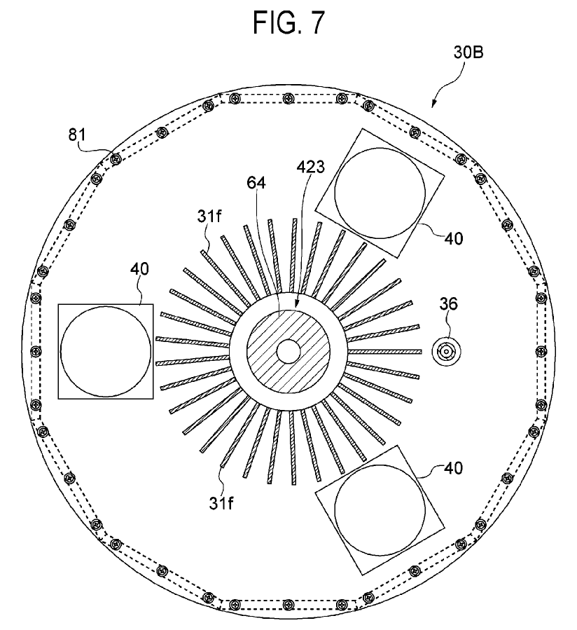

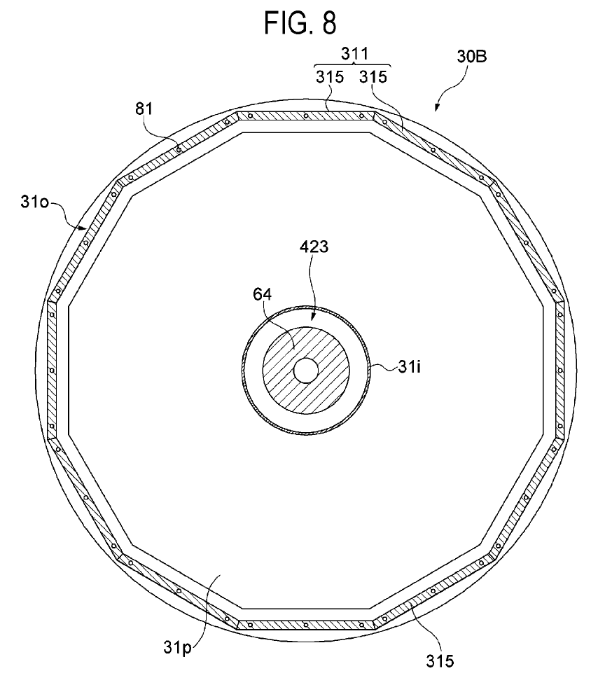

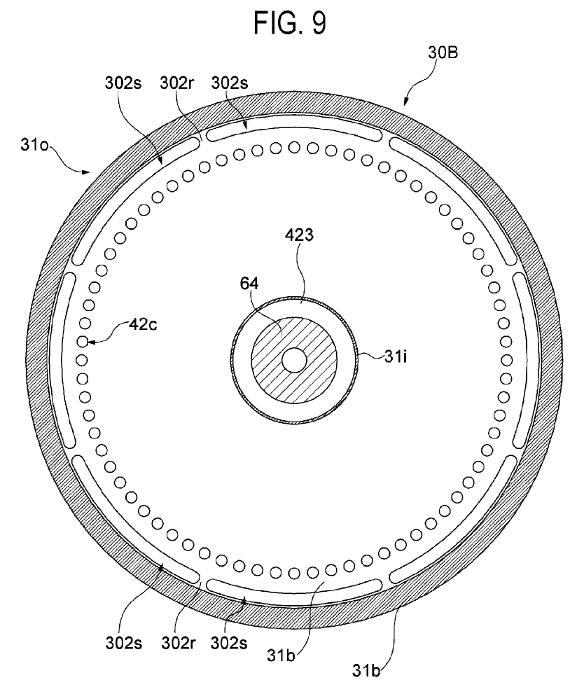

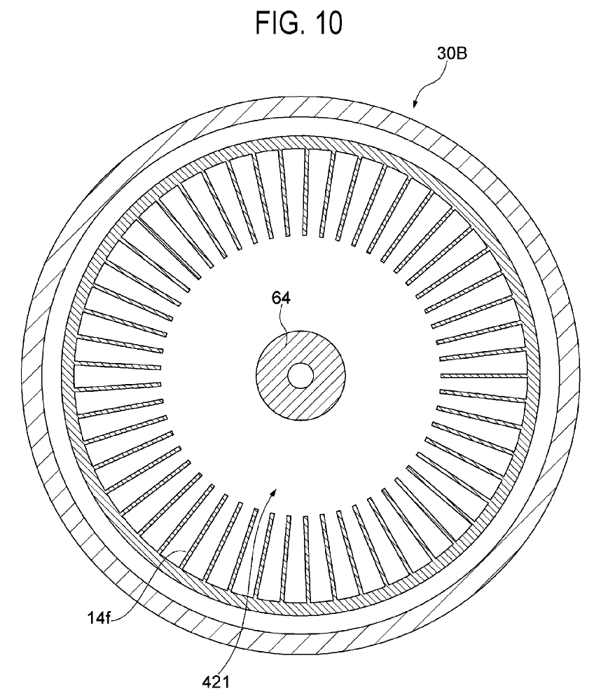

A plasma processing apparatus according to another exemplary embodiment will be described below with reference to FIGS. 6 to 10. FIG. 6 is a diagram illustrating a plasma processing apparatus according to another exemplary embodiment. FIG. 7 is a cross-sectional view taken along line VII-VII in FIG. 6. FIG. 8 is a cross-sectional view taken along line VIII-VIII in FIG. 6. FIG. 9 is a cross-sectional view taken along line IX-IX in FIG. 6. FIG. 10 is a cross-sectional view taken along line X-X in FIG. 6. A plasma processing apparatus 1B illustrated in FIGS. 6 to 10 will be described below with a focus on differences from the plasma processing apparatus 1.

The plasma processing apparatus 1B includes a resonator 30B instead of the resonator 30. The resonator 30B is provided above the excitation electrode 14. Just like the resonator 30, the resonator 30B includes a waveguide 32 which is defined by a conductor part 31. In the resonator 30B, the waveguide 32 also includes a plurality of layers 320. Just like the conductor part 31 of the resonator 30, the conductor part 31 of the resonator 30B also includes a first portion 311 and a second portion 312.

In the temperature regulator 18 of the plasma processing apparatus 1B, the flow path 42 is formed in substantially the same manner as the flow path 42 of the plasma processing apparatus 1. Further, the partial flow path 422 of the temperature regulator 18 of the plasma processing apparatus 1B is formed by the waveguide 32 of the resonator 30B. However, in the temperature regulator 18 of the plasma processing apparatus 1B, the partial flow path 422 is connected to the partial flow path 421 via a plurality of communication holes 42c formed in the conductor plate 31b. The plurality of communication holes 42c penetrate the conductor plate 31b and are arranged in the circumferential direction around the axis AX.

In the plasma processing apparatus 1B, the heat medium is supplied from the plurality of fans 40 to the partial flow path 421 via the plurality of openings 42b and the partial flow path 422, and flows through the partial flow path 421 along the upper surface of the excitation electrode 14. Accordingly, heat exchange occurs between the excitation electrode 14 and the heat medium. Then, the heat medium flows from the partial flow path 421 to the partial flow path 423. The heat medium is discharged from the partial flow path 423 to the outside of the plasma processing apparatus 1B via the opening 42a.

In the plasma processing apparatus 1B, the upper wall 31u of the resonator 30B may have a plurality of fins 31f. The plurality of fins 31f protrude upward. The plurality of fins 31f extend in the radial direction with respect to the axis AX and are arranged along the circumferential direction around the axis AX. A heat insulating plate 80 may be disposed on the plurality of fins 31f. The heat insulating plate 80 is formed of, for example, polyimide.

A plurality of flow paths is provided between adjacent ones of the plurality of fins 31f. The plurality of flow paths provided by the plurality of fins 31f extend in the radial direction with respect to the axis AX and are arranged along the circumferential direction around the axis AX. The partial flow path 423 and the opening 42a are connected to each other via the flow paths provided by the plurality of fins 31f. According to this embodiment, the heat medium is cooled by the plurality of fins 31f and then discharged to the outside of the plasma processing apparatus 1B via the opening 42a.

In the plasma processing apparatus 1B, the outer portion 31o is formed in a substantially cylindrical shape having a central axis centered at the axis AX. In the plasma processing apparatus 1B, the outer portion 31o may extend along each side of a polygon in a cross section perpendicular to the axis AX. That is, the outer portion 31o may have a polygonal tube shape. The outer portion 31o may be constituted with a plurality of plates 315 between the adjacent conductor plates 31p in the vertical direction. Each of the plurality of plates 315 is formed of a metal. Each of the plurality of plates 315 may be a flat plate. Each of the plurality of plates 315 extends along a corresponding side of the polygon in the cross section perpendicular to the axis AX.

In the plasma processing apparatus 1B as well, the plurality of plates 315 which constitute the first portion 311 are formed of the first conductor described above. The second portion 312 is formed of the second conductor described above. The second portion 312 includes the plurality of plates 315 which constitute the second portion 312. In the plasma processing apparatus 1B as well, the second portion 312 may be the entire portion of the conductor part 31 other than the first portion 311.

Even in the plasma processing apparatus 1B, the first portion 311 has a low thermal conductivity, which suppresses the conduction of heat from the excitation electrode 14 via the resonator 30B. Therefore, the power consumption of the heater power supply 22 is suppressed. Further, in the first portion 311, a voltage of a standing wave is maximized and a current of the standing wave is minimized. Therefore, according to the plasma processing apparatus 1B, a current loss in the resonator 30B is suppressed.

In the plasma processing apparatus 1B, each of the plurality of plates 315 is fixed to the conductor plate 31p located at an upper side thereof and the conductor plate 31p located at a lower side thereof by one or more screws 81. The one or more screws 81 may be formed of the first conductor described above. In this case, a difference in thermal expansion coefficient between each of the plurality of plates 315 constituting the first portion 311 and the one or more screws 81 is reduced. Therefore, damage to the one or more screws 81 is suppressed.

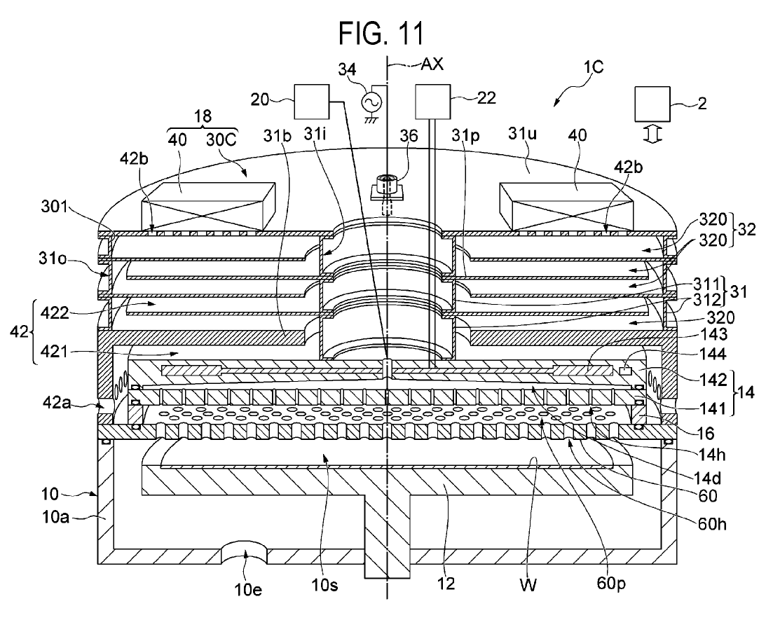

Next, a plasma processing apparatus according to another exemplary embodiment will be described with reference to FIG. 11. FIG. 11 is a diagram illustrating a plasma processing apparatus according to another exemplary embodiment. A plasma processing apparatus 1C illustrated in FIG. 11 will be described below with a focus on differences from the plasma processing apparatus 1.

The plasma processing apparatus 1C further includes an electrode 60. The electrode 60 is another excitation electrode. The electrode 60 has a substantially disk-like shape and is disposed so as to close the upper end opening of the chamber 10. The electrode 60 is provided with a plurality of holes 60h. The plurality of holes 60h penetrate the electrode 60 in the thickness direction. The excitation electrode 14 is disposed above the electrode 60. A plasma generation space 60p is defined between the excitation electrode 14 and the electrode 60. The emitter 16 surrounds the plasma generation space 60p and is interposed between the excitation electrode 14 and the electrode 60. In the plasma processing apparatus 1C, the plasma generation space 60p is provided above the processing space 10s so as to be spaced apart from the processing space 10s.

In the plasma processing apparatus 1C, a gas from the gas supply 20 is supplied to the plasma generation space 60p via the gas diffusion chamber 14d and the plurality of gas holes 14h. In the plasma generation space 60p, plasma is generated from the gas by the electromagnetic wave introduced into the plasma generation space 60p from the emitter 16. Active species in the plasma generated in the plasma generation space 60p are supplied to the processing space 10s via the plurality of holes 60h.

The plasma processing apparatus 1C further includes a resonator 30C instead of the resonator 30. The resonator 30C is provided above the excitation electrode 14. Just like the resonator 30, the resonator 30C includes a waveguide 32 defined by a conductor part 31. In the resonator 30C, the waveguide 32 also includes a plurality of layers 320. Just like the conductor part 31 of the resonator 30, the conductor part 31 of the resonator 30 also includes a first portion 311 and a second portion 312. However, in the resonator 30C, the first end 301, that is, an end portion opposite one end of the waveguide 32, is located at a radial center of the plasma generation space 60p.

In the resonator 30C, the outer portion 31o may be formed in a substantially cylindrical shape. In the resonator 30C, the first portion 311 is included in the inner portion 31i and extends along an inner side of one or more intermediate layers 320 among the plurality of layers 320. In the plasma processing apparatus 1C as well, the first portion 311 is formed of the first conductor described above. Further, the second portion 312 is formed of the second conductor described above. In the plasma processing apparatus 1C as well, the second portion 312 may be the entire portion of the conductor part 31 other than the first portion 311.

Even in the plasma processing apparatus 1C, the first portion 311 has a low thermal conductivity, which suppresses the conduction of heat from the excitation electrode 14 via the resonator 30C. Therefore, the power consumption of the heater power supply 22 is suppressed. Further, in the first portion 311, a voltage of a standing wave is maximized and a current of the standing wave is minimized. Therefore, according to the plasma processing apparatus 1C, the current loss in the resonator 30C is suppressed.

In the temperature regulator 18 of the plasma processing apparatus 1C, the flow path 42 includes a partial flow path 421 and a partial flow path 422. The partial flow path 422 of the temperature regulator 18 of the plasma processing apparatus 1C is formed using the waveguide 32 of the resonator 30C. In the temperature regulator 18 of the plasma processing apparatus 1C, the flow path 42 extends from a plurality of openings 42b to a plurality of openings 42a. The plurality of openings 42b are inlets through which the heat medium flows to the flow path 42 and are connected to the partial flow path 422. Each of the plurality of openings 42b is open directly below a corresponding fan among the plurality of fans 40. The plurality of openings 42a are outlets through which the heat medium flows out from the flow path 42 and are connected to the partial flow path 421. The plurality of openings 42a are arranged along the circumferential direction around the axis AX. In one embodiment, the plurality of openings 42a are formed in the outer portion 31o of the resonator 30C.

In the plasma processing apparatus 1C, the heat medium is supplied from the plurality of fans 40 to the partial flow path 421 via the plurality of openings 42b and the partial flow path 422, and flows through the partial flow path 421 along the upper surface of the excitation electrode 14. Accordingly, heat exchange occurs between the excitation electrode 14 and the heat medium. The heat medium is then discharged from the partial flow path 421 to the outside of the plasma processing apparatus 1C via the plurality of openings 42a.

Although various exemplary embodiments have been described above, the present disclosure is not limited to the above-described exemplary embodiments, and various additions, omissions, substitutions, and modifications may be made. Further, elements in different embodiments may be combined with each other to form other embodiments.

Various exemplary embodiments included in the present disclosure are now recited in [E1] to [E12] below.

### [E1]

A plasma processing apparatus includes:

a chamber which provides a processing space in an interior of the chamber;

a substrate support provided in the processing space;

an excitation electrode provided above the substrate support;

an emitter provided to emit an electromagnetic wave to a plasma generation space below the excitation electrode; and

a resonator provided above the excitation electrode and electromagnetically coupled to the emitter,

wherein the resonator includes a conductor part constituting a waveguide,

wherein the conductor part is formed with a first conductor and a second conductor, the first conductor being provided in a first portion which extends from a first end of the waveguide to a position corresponding to a quarter of a wavelength in the waveguide of the electromagnetic wave inside the resonator, and the second conductor being provided in a second portion other than the first portion, and

wherein a thermal conductivity of the first conductor is lower than a thermal conductivity of the second conductor.

### [E2]

In the plasma processing apparatus of [E1] above, the waveguide has a structure in which a plurality of folded portions is provided, and

wherein the first portion extends along one of the plurality of folded portions.

### [E3]

In the plasma processing apparatus of [E2] above, the emitter extends around a central axis of the chamber and the excitation electrode,

wherein the conductor part includes an inner portion and an outer portion extending coaxially with respect to the central axis, and a plurality of conductor plates arranged parallel to one another along a vertical direction in which the central axis extends,

wherein the waveguide includes a plurality of layers extending between the outer portion and the inner portion and arranged alternately with the plurality of conductor plates, and

wherein each layer of the plurality of layers of the waveguide is connected to an upperlying layer located above the respective layer among the plurality of layers and one of the plurality of folded portions arranged along the inner portion or the outer portion.

### [E4]

In the plasma processing apparatus of [E3] above, the first portion is included in the outer portion.

### [E5]

In the plasma processing apparatus of [E3] or [E4] above, wherein the first end is an outer peripheral end of an uppermost layer among the plurality of layers,

wherein the waveguide further includes a second end which is an outer peripheral end of a lowermost layer among the plurality of layers, and

wherein the plasma generation space is provided below the excitation electrode and inside the processing space.

### [E6]

In the plasma processing apparatus of [E3] above, the first portion is included in the inner portion.

### [E7]

The plasma processing apparatus of [E6] above further includes:

an additional electrode interposed between the excitation electrode and the processing space and configured to provide a plurality of holes connecting the plasma generation space and the processing space,

wherein the emitter is provided between the excitation electrode and the additional electrode.

### [E8]

In the plasma processing apparatus of any one of [E3] to [E7] above, a thickness of a wall constituting the inner portion is smaller than a thickness of a wall constituting the outer portion.

### [E9]

In the plasma processing apparatus of any one of [E1] to [E8] above, the excitation electrode includes a heating mechanism.

### [E10]

In the plasma processing apparatus of [E9] above, the heating mechanism is an electric heater.

### [E11]

The plasma processing apparatus of any one of [E1] to [E10] above further includes:

a fan configured to form a flow of gas through the waveguide between a surface of the excitation electrode and an exterior of the resonator.

### [E12]

In the plasma processing apparatus of any one of [E1] to [E11] above, the first conductor includes stainless steel or brass, and

wherein the second conductor includes aluminum or copper.

According to the present disclosure in some embodiments, it is possible to provide a technology capable of suppressing heat conduction from an excitation electrode of a plasma processing apparatus via a resonator and suppressing a current loss.

From the foregoing, it will be understood that various embodiments of the present disclosure have been described herein for purpose of description, and that various modifications may be made without departing from the scope and spirit of the present disclosure. Accordingly, the various embodiments disclosed herein are not intended to be limiting, and the true scope and spirit of the present disclosure is indicated by the appended claims.

What is claimed is:

1. A plasma processing apparatus, comprising:
a chamber which provides a processing space in an interior of the chamber;
a substrate support provided in the processing space;
an excitation electrode provided above the substrate support;
an emitter provided to emit an electromagnetic wave to a plasma generation space below the excitation electrode; and
a resonator provided above the excitation electrode and electromagnetically coupled to the emitter,
wherein the resonator includes a conductor part constituting a waveguide,
wherein the conductor part is formed with a first conductor and a second conductor, the first conductor being provided in a first portion which extends from a first end of the waveguide to a position corresponding to a quarter of a wavelength in the waveguide of the electromagnetic wave inside the resonator, and the second conductor being provided in a second portion other than the first portion, and
wherein a thermal conductivity of the first conductor is lower than a thermal conductivity of the second conductor.

2. The plasma processing apparatus of claim 1, wherein the waveguide has a structure in which a plurality of folded portions is provided, and
wherein the first portion extends along one of the plurality of folded portions.

3. The plasma processing apparatus of claim 2, wherein the emitter extends around a central axis of the chamber and the excitation electrode,
wherein the conductor part includes an inner portion and an outer portion extending coaxially with respect to the central axis, and a plurality of conductor plates arranged parallel to one another along a vertical direction in which the central axis extends,
wherein the waveguide includes a plurality of layers extending between the outer portion and the inner portion and arranged alternately with the plurality of conductor plates, and
wherein each layer of the plurality of layers of the waveguide is connected to an upperlying layer located above the respective layer among the plurality of layers and one of the plurality of folded portions arranged along the inner portion or the outer portion.

4. The plasma processing apparatus of claim 3, wherein the first portion is included in the outer portion.

5. The plasma processing apparatus of claim 4, wherein the first end is an outer peripheral end of an uppermost layer among the plurality of layers,
wherein the waveguide further includes a second end which is an outer peripheral end of a lowermost layer among the plurality of layers, and
wherein the plasma generation space is provided below the excitation electrode and inside the processing space.

6. The plasma processing apparatus of claim 3, wherein the first portion is included in the inner portion.

7. The plasma processing apparatus of claim 6, further comprising:
an additional electrode interposed between the excitation electrode and the processing space and configured to provide a plurality of holes connecting the plasma generation space and the processing space,
wherein the emitter is provided between the excitation electrode and the additional electrode.

8. The plasma processing apparatus of claim 3, wherein a thickness of a wall constituting the inner portion is smaller than a thickness of a wall constituting the outer portion.

9. The plasma processing apparatus of claim 5, wherein a thickness of a wall constituting the inner portion is smaller than a thickness of a wall constituting the outer portion.

10. The plasma processing apparatus of claim 1, wherein the excitation electrode includes a heating mechanism.

11. The plasma processing apparatus of claim 5, wherein the excitation electrode includes a heating mechanism.

12. The plasma processing apparatus of claim 10, wherein the heating mechanism is an electric heater.

13. The plasma processing apparatus of claim 1, further comprising:
a fan configured to form a flow of gas through the waveguide between a surface of the excitation electrode and an exterior of the resonator.

14. The plasma processing apparatus of claim 5, further comprising:
a fan configured to create a flow of gas through the waveguide between a surface of the excitation electrode and an exterior of the resonator.

15. The plasma processing apparatus of claim 1, wherein the first conductor includes stainless steel or brass, and
wherein the second conductor includes aluminum or copper.

16. The plasma processing apparatus of claim 5, wherein the first conductor includes stainless steel or brass, and
wherein the second conductor includes aluminum or copper.
